(19) United States
(12) Patent Application Publication
(10) Pub. No.: US 2011/0031606 A1
(43) Pub. Date: Feb. 10, 2011

(54) PACKAGING SUBSTRATE HAVING EMBEDDED SEMICONDUCTOR CHIP

(75) Inventors: Yen-Ju Chen, Taoyuan (TW); Che-Wei Hsu, Taoyuan (TW); Kan-Jung Chia, Taoyuan (TW)

Correspondence Address: EDWARDS ANGELL PALMER & DODGE LLP, P.O. BOX 55874, BOSTON, MA, 02205, US

(73) Assignee: UNIMICRON TECHNOLOGY CORPORATION, Taoyuan (TW)

(21) Appl. No.: 12/852,052

(22) Filed: Aug. 6, 2010

(30) Foreign Application Priority Data
Aug. 10, 2009 (TW) 098126677

(51) Int. Cl. H01L 23/48; H01L 23/08

(52) U.S. Cl. 257/690; 257/E23.01; 257/E23.002

(57) ABSTRACT

A packaging substrate includes: a core board having opposite first and second surfaces and a cavity penetrating therethrough; a semiconductor chip disposed in the cavity and having an active surface with electrode pads and an opposite inactive surface; a first reinforcing dielectric layer containing a reinforcing material disposed on the first surface and the active surface and filling the gap between the chip and the cavity; a second reinforcing dielectric layer containing a reinforcing material disposed on the second surface and the inactive surface and filling the gap between the chip and the cavity; and first and second wiring layers disposed on the first and second reinforcing dielectric layers respectively and the first wiring layer electrically connecting to the electrode pads. The first and second reinforcing dielectric layers enhance the support force of the entire structure to thereby prevent delamination of the wiring layers from the dielectric layers and increase product yield and reliability.

### BACKGROUND OF THE INVENTION

1. Field of the Invention

The present invention relates generally to packaging substrates having embedded semiconductor chips, and more particularly, to a reinforced packaging substrate structure.

2. Description of Related Art

Along with the development of semiconductor packaging technologies, the electronic industry has developed various types of semiconductor device packages. A method for fabricating a semiconductor device package mainly involves mounting a semiconductor chip on a packaging substrate or a lead frame, electrically connecting the semiconductor chip to the substrate or the lead frame, and encapsulating the semiconductor chip with an encapsulant. BGA (Ball Grid Array) packaging technology is an advanced semiconductor packaging technology, which is characterized in a plurality of grid array arranged solder balls disposed on a packaging substrate such that the same unit area can accommodate more I/O connections, thereby meeting requirements of highly integrated semiconductor chips. Further, the entire packaging unit can be bonded and electrically connected to an external device through the solder balls.

In a BGA packaging structure, a semiconductor chip is mounted by its inactive surface to the front side of the packaging substrate and electrically connected to the packaging substrate through wire bonding, or in a flip-chip manner, a semiconductor chip is mounted by its active surface to the front side of the packaging substrate and electrically connected to the packaging substrate through solder bumps; then the solder balls mounted to the back side of the packaging substrate are used for electrically connecting to an external device. Although such a wire-bonding package structure achieves high pin count, too long wire connecting path increases impedance, decreases signal transmitting efficiency and limits performance of the semiconductor chip under high-frequency or high-speed operation. While for a flip-chip package structure, it would be difficult to control the reliability of the device and achieve fine pitch requirement in that the device is provided with solder bumps. In view of poor control of average of the volume or height of the solder bumps, particularly if the solder bumps are formed with a smaller volume and height, the underfill filling would be adversely affected, and cracking and delamination would thus occur. On the other hand, if the solder bumps are formed with a larger volume and height, bridging and short-circuit would occur. Furthermore, poor control of common difference of the volume or height of the solder bumps would lead to poor electricity. Also, since the solder bumps are usually formed as a grid array, said poor control of common difference would lead to poor coplanarity and result in disequilibrium of stress. Therefore, it would be difficult to control the reliability of the device which applies solder bumps for connecting the electrode pads of a semiconductor chip.

In order to efficiently enhance the electrical performance of next generation products, the electronic industry has developed packaging substrate structures having embedded semiconductor chips, wherein semiconductor chips are embedded in packaging substrates and wiring layers are formed through built-up processes so as to electrically connect to the semiconductor chip, thereby shortening electrical connecting path, reducing electrical signal loss and distortion and enhancing performance of the semiconductor chips under high-speed operation.

FIGS. 1A to 1E shows a method for fabricating a conventional packaging substrate having an embedded semiconductor chip.

Referring to FIG. 1A, a core board 10 is provided, which has a first surface 10a and an opposite second surface 10b and a cavity 100 penetrating the first surface 10a and the second surface 10b.

Referring to FIG. 1B, a semiconductor chip 11 having an active surface 11a with a plurality of electrode pads 110 and an opposite inactive surface 11b is disposed in the cavity 100.

Referring to FIG. 1C, a first initial dielectric layer 12a is formed on the first surface 10a and the active surface 11a of the semiconductor chip 11, and a second initial dielectric layer 12b is formed on the second surface 10b and the inactive surface 11b of the semiconductor chip 11. The first and second initial dielectric layers 12a,12b also fill the gap between the cavity 100 and the semiconductor chip 11 so as to fix the semiconductor chip 11 in the cavity 100. Thereafter, a plurality of vias 120a are formed in the first initial dielectric layer 12a so as to expose the electrode pads 110, correspondingly, and a plurality of through holes 101 are formed to penetrate the first initial dielectric layer 12a, the core board 10 and the second initial dielectric layer 12b.

Referring to FIG. 1D, first and second wiring layers 13a,13b are formed on the first and second initial dielectric layers 12a,12b, respectively, conductive vias 131 are formed in the vias 120a, correspondingly, so as to electrically connect the first wiring layer 13a and the semiconductor chip 11, and conductive through holes 132 are formed in the through holes 101, correspondingly, so as to electrically connect the first wiring layer 13a and the second wiring layer 13b.

Referring to FIG. 1E, a first built-up structure 14a is formed on the first initial dielectric layer 12a and the first wiring layer 13a, and a second built-up structure 14b is formed on the second initial dielectric layer 12b and the second wiring layer 13b. The first built-up structure 14a has at least a first dielectric layer 141a, a first built-up wiring layer 142a disposed on the first dielectric layer 141a, and a plurality of first built-up conductive vias 143a disposed in the first dielectric layer 141a and electrically connecting the first wiring layer 13a and the first built-up wiring layer 142a, wherein the outermost first built-up wiring layer 142a of the first built-up structure 14a has a plurality of first conductive pads 144a. A first solder mask layer 15a is further formed on the first built-up structure 14a and has a plurality of first openings 150a for exposing the first conductive pads 144a, correspondingly. The second built-up structure 14b has at least a second dielectric layer 141b, a second built-up wiring layer 142b disposed on the second dielectric layer 141b, and a plurality of second built-up conductive vias 143b disposed in the second dielectric layer 141b and electrically connecting the second wiring layer 13b and the second built-up wiring layer 142b, wherein the outermost second built-up wiring layer 142b of the second built-up structure 14b has a plurality of second conductive pads 144b. A second solder mask layer 15b is further formed on the second built-up structure 14b and has a plurality of second openings 150b for exposing the second conductive pads 144b, correspondingly.

However, during a hardening process, the first and second initial dielectric layers 12a, 12b easily contract to form recesses in the area between the semiconductor chip 11 and the cavity 100, which can cause delamination between the first wiring layer 13a and the first initial dielectric layer 12a.

Further, recesses formed in the area between the semiconductor chip 11 and the cavity 100 can adversely affect the subsequent formation of the first dielectric layer 141a and the first built-up wiring layer 142a of the first built-up structure 14a and even cause formation of recesses on the first dielectric layer 141a and the first built-up wiring layer 142a, thereby resulting in poor bonding between the first dielectric layer 141a and the first built-up wiring layer 142a.

Furthermore, since the thickness of the first and second initial dielectric layer 12a, 12b is quite small, the core board 10 lacks sufficient rigidity and accordingly warpages can easily occur to the packaging substrate having embedded semiconductor chip.

Therefore, it is imperative to provide a packaging substrate having an embedded semiconductor chip so as to overcome the above drawbacks.

### SUMMARY OF THE INVENTION

In view of the above drawbacks of the prior art, it is an object of the present invention to provide a packaging substrate having an embedded semiconductor chip so as to enhance the support force of the entire structure and avoid warpages.

Another object of the present invention is to provide a packaging substrate having an embedded semiconductor chip so as to avoid delamination of a wiring layer from a dielectric layer of the packaging substrate and increase product reliability.

In order to achieve the above and other objects, the present invention provides a packaging substrate having an embedded semiconductor chip, which comprises: a core board having a first surface and an opposite second surface and a cavity penetrating the first and second surfaces; a semiconductor chip disposed in the cavity and having an active surface with a plurality of electrode pads and an opposite inactive surface; a first reinforcing dielectric layer disposed on the first surface of the core board and the active surface of the semiconductor chip and filling the gap between the semiconductor chip and the cavity, wherein the first reinforcing dielectric layer comprises a reinforcing material; a second reinforcing dielectric layer disposed on the second surface of the core board and the inactive surface of the semiconductor chip and filling the gap between the semiconductor chip and the cavity, wherein the second reinforcing dielectric layer comprises a reinforcing material; and first and second wiring layers disposed on the first and second reinforcing dielectric layers, respectively, and the first wiring layer electrically connecting to the electrode pads.

Therein, the core board can be one of an insulation board, a metal board and a wiring board having an inner wiring layer.

In the above-described structure, the first reinforcing dielectric layer can further have a plurality of vias for exposing the electrode pads, correspondingly, and conductive vias are disposed in the vias, correspondingly, so as to electrically connect the first wiring layer and the electrode pads; the substrate can further comprise a plurality of through holes penetrating the first reinforcing dielectric layer, the core board and the second reinforcing dielectric layer, and conductive through holes are disposed in the through holes, correspondingly, so as to electrically connect the first and second wiring layers. In addition, in the case the core board is a wiring board having an inner wiring layer, the conductive through holes further electrically connect to the inner wiring layer of the wiring board.

In the above-described structure, the first and second reinforcing dielectric layers can be made of the same or different materials.

The above-described structure can further comprise a first built-up structure disposed on the first reinforcing dielectric layer and the first wiring layer and electrically connecting to the first wiring layer; and a second built-up structure disposed on the second reinforcing dielectric layer and the second wiring layer and electrically connecting to the second wiring layer.

Therein, the first built-up structure has at least a first dielectric layer, a first built-up wiring layer disposed on the first dielectric layer, and a plurality of first built-up conductive vias disposed in the first dielectric layer and electrically connecting the first wiring layer and the first built-up wiring layer, the outermost first built-up wiring layer of the first built-up structure having a plurality of first conductive pads. Further, a first solder mask layer can be disposed on the first built-up structure and have a plurality of first openings for exposing the first conductive pads, correspondingly.

The second built-up structure has at least a second dielectric layer, a second built-up wiring layer disposed on the second dielectric layer, and a plurality of second built-up conductive vias disposed in the second dielectric layer and electrically connecting the second wiring layer and the second built-up wiring layer, the outermost second built-up wiring layer of the second built-up structure having a plurality of second conductive pads. Further, a second solder mask layer can be disposed on the second built-up structure and have a plurality of second openings for exposing the second conductive pads, correspondingly.

According to the present invention, a core board having a first surface and an opposite second surface is provided, a semiconductor chip having an active surface and an opposite inactive surface is received in a cavity of the core board, a first reinforcing dielectric layer comprising a reinforcing material such as glass fiber is disposed on the first surface of the core board and the active surface of the semiconductor chip, and a second reinforcing dielectric layer comprising a reinforcing material such as glass fiber is disposed on the second surface of the core board and the inactive surface of the semiconductor chip. The application of the first and second reinforcing dielectric layers enhances the support force of the entire structure so as to prevent warpages of the first and second reinforcing dielectric layers which otherwise can occur due to contraction of dielectric layers during a hardening process as in the prior art. In addition, the application of the first and second reinforcing dielectric layers avoids formation of recesses as in the prior art, thereby preventing delamination of the wiring layers electrically connecting to the semiconductor chip from the dielectric layers and increasing product yield and reliability.

### BRIEF DESCRIPTION OF DRAWINGS

FIGS. 1A to 1E are cross-sectional views showing a method for fabricating a conventional packaging substrate having an embedded semiconductor chip; and

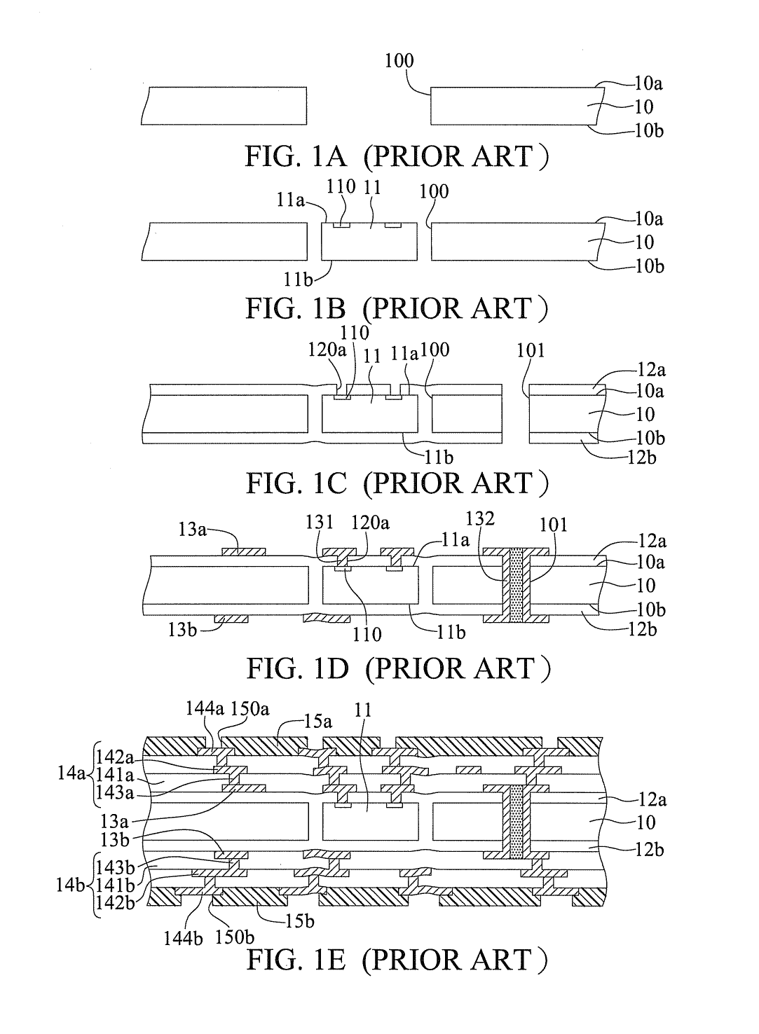

FIGS. 2A to 2E are cross-sectional views showing a method for fabricating a packaging substrate having an embedded semiconductor chip according to the present invention.

### DETAILED DESCRIPTION OF PREFERRED EMBODIMENTS

The following illustrative embodiments are provided to illustrate the disclosure of the present invention, these and other advantages and effects can be apparent to those in the art after reading this specification.

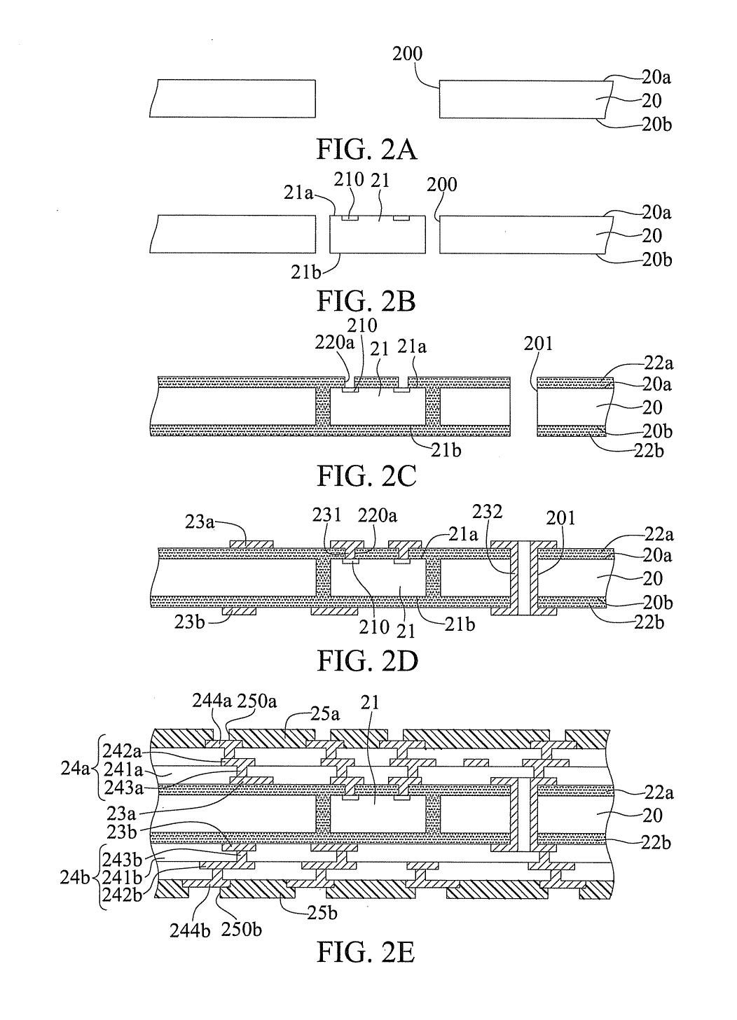

FIGS. 2A to 2E are cross-sectional views showing a method for fabricating a packaging substrate having an embedded semiconductor chip according to the present invention. Referring to FIG. 2A, a core board 20 having a first surface 20a and an opposite second surface 20b is provided and a cavity 200 penetrating the first surface 20a and the second surface 20b is disposed in the core board 20. The core board 20 can be an insulation board, a metal board, or a wiring board having an inner wiring layer. Since the structure of the core board 20 is well known in the art, detailed description thereof is omitted herein.

Referring to FIG. 2B, a semiconductor chip 21 having an active surface 21a with a plurality of electrode pads 210 and an opposite inactive surface 21b is received in the cavity 200.

Referring to FIG. 2C, a first reinforcing dielectric layer 22a is formed on the first surface 20a of the core board 20 and the active surface 21a of the semiconductor chip 21, wherein the first reinforcing dielectric layer 22a comprises a reinforcing material; and a second reinforcing dielectric layer 22b is formed on the second surface 20b of the core board 20 and the inactive surface 21b of the semiconductor chip 21, wherein the second reinforcing dielectric layer 22b comprises a reinforcing material. Further, the first and second reinforcing dielectric layers 22a,22b fill the gap between the cavity 200 and the semiconductor chip 21 so as to fix the semiconductor chip 21 in the cavity 200. Therein, the reinforcing material is a glass fiber material. The application of the first and second reinforcing dielectric layers 22a,22b enhances the support force of the entire structure and avoids formation of recesses on the surfaces of the first and second reinforcing dielectric layers 22a,22b located between the semiconductor chip 21 and the cavity 200 as in the prior art. Further, a plurality of vias 220a are formed in the first reinforcing dielectric layer 22a for exposing the electrode pads 210, correspondingly, and a plurality of through holes 201 are formed to penetrate the first reinforcing dielectric layer 22a, the core board 20 and the second reinforcing dielectric layer 22b. It should be noted that the first and second reinforcing dielectric layers 22a,22b can be made of the same or different materials.

Referring to FIG. 2D, first and second wiring layers 23a,23b are formed on the first and second reinforcing dielectric layers 22a,22b, respectively, conductive vias 231 are formed in the vias 220a, correspondingly, so as to electrically connect the first wiring layer 23a and the semiconductor chip 21, and conductive through holes 232 are formed in the through holes 201, correspondingly, so as to electrically connect the first wiring layer 23a and the second wiring layer 23b. Further, if the core board 20 is a wiring board having an inner wiring layer, the conductive through holes 232 further electrically connect to the inner wiring layer of the wiring board.

Since no recess is formed on the surfaces of the first and second reinforcing dielectric layer 22a,22b located between the semiconductor chip 21 and the cavity 200, delamination is prevented from occurring between the first wiring layer 23a electrically connecting to the semiconductor chip 21 and the first reinforcing dielectric layer 22a, thus increasing product yield and reliability.

Referring to FIG. 2E, a first built-up structure 24a is formed on the first reinforcing dielectric layer 22a and the first wiring layer 23a, and a second built-up structure 24b is formed on the second reinforcing dielectric layer 22b and the second wiring layer 23b. Therein, the first built-up structure 24a has at least a first dielectric layer 241a, a first built-up wiring layer 242a disposed on the first dielectric layer 241a, and a plurality of first built-up conductive vias 243a disposed in the first dielectric layer 241a and electrically connecting the first wiring layer 23a and the first built-up wiring layer 242a, the outermost first built-up wiring layer 242a of the first built-up structure 24a having a plurality of first conductive pads 244a. A first solder mask layer 25a is further formed on the first built-up structure 24a and has a plurality of first openings 250a for exposing the first conductive pads 244a, correspondingly. The first conductive pads 244a can be bonding pads or ball pads for electrically connecting to an external electronic device such as a semiconductor chip or a passive component. The second built-up structure 24b has at least a second dielectric layer 241b, a second built-up wiring layer 242b disposed on the second dielectric layer 241b, and a plurality of second built-up conductive vias 243b disposed in the second dielectric layer 241b and electrically connecting the second wiring layer 23b and the second built-up wiring layer 242b, the outermost second built-up wiring layer 242b of the second built-up structure 24b having a plurality of second conductive pads 244b. A second solder mask layer 25b is further formed on the second built-up structure 24b and has a plurality of second openings 250b such that the second conductive pads 244b can be exposed from the second openings 250b, correspondingly, for electrically connecting to an external electronic device such as a printed circuit board.

Since no delamination occurs between the first wiring layer 23a and the first reinforcing dielectric layer 22a, the first dielectric layer 241a of the first built-up structure 24a has good bonding with the first built-up wiring layer 242a. As such, the entire packaging substrate has preferred rigidity so as to prevent warpages from occurring as in the prior art.

According to the above-described method, the present invention obtains a packaging substrate having an embedded semiconductor chip, which comprises: a core board 20 having a first surface 20a and an opposite second surface 20b and a cavity 200 penetrating the first surface 20a and the second surface 20b; a semiconductor chip 21 disposed in the cavity 200 and having an active surface 21a with a plurality of electrode pads 210 and an opposite inactive surface 21b; a first reinforcing dielectric layer 22a disposed on the first surface 20a of the core board 20 and the active surface 21a of the semiconductor chip 21 and filling the gap between the semiconductor chip 21 and the cavity 200, wherein the first reinforcing dielectric layer 22a comprises a reinforcing material; a second reinforcing dielectric layer 22b disposed on the second surface 20b of the core board 20 and the inactive surface 21b of the semiconductor chip 21 and filling the gap between the semiconductor chip 21 and the cavity 200, wherein the second reinforcing dielectric layer 22b comprises a reinforcing material; first and second wiring layers 23a,23b disposed on the first and second reinforcing dielectric layers 22a,22b, respectively, and the first wiring layer 23a electrically connecting to the electrode pads 210.

Therein, the core board 20 can be an insulation board, a metal board or a wiring board having an inner wiring layer.

The reinforcing material can be a glass fiber material. The first and second reinforcing dielectric layers 22a,22b can be made of the same or different materials. The first reinforcing dielectric layer 22a further has a plurality of vias 220a for exposing the electrode pads 210, correspondingly, and a plurality of through holes 201 are provided to penetrate the first reinforcing dielectric layer 22a, the core board 20 and the second reinforcing dielectric layer 22b.

Further, conductive vias 231 are disposed in the vias 220a, correspondingly, so as to electrically connect the first wiring layer 23a and the electrode pads 210 of the semiconductor chip 21; and conductive through holes 232 are disposed in the through holes 201, correspondingly, so as to electrically connect the first and second wiring layers 23a,23b. In addition, if the core board 20 is a wiring board having an inner wiring layer, the conductive through holes 232 further electrically connect to the inner wiring layer of the wiring board.

The packaging substrate of the present invention can further comprise a first built-up structure 24a disposed on the first reinforcing dielectric layer 22a and the first wiring layer 23a and electrically connecting to the first wiring layer 23a; and a second built-up structure 24b disposed on the second reinforcing dielectric layer 22b and the second wiring layer 23b and electrically connecting to the second wiring layer 23b.

The first built-up structure 24a has at least a first dielectric layer 241a, a first built-up wiring layer 242a disposed on the first dielectric layer 241a, and a plurality of first built-up conductive vias 243a disposed in the first dielectric layer 241a and electrically connecting the first wiring layer 23a and the first built-up wiring layer 242a, wherein the outermost first built-up wiring layer 242a of the first built-up structure 24a has a plurality of first conductive pads 244a. A first solder mask layer 25a is further disposed on the first built-up structure 24a and has a plurality of first openings 250a for exposing the first conductive pads 244a, correspondingly.

The second built-up structure 24b has at least a second dielectric layer 241b, a second built-up wiring layer 242b disposed on the second dielectric layer 241b, and a plurality of second built-up conductive vias 243b disposed in the second dielectric layer 241b and electrically connecting the second wiring layer 23b and the second built-up wiring layer 242b, wherein the outermost second built-up wiring layer 242b of the second built-up structure 24b has a plurality of second conductive pads 244b. A second solder mask layer 25b is further disposed on the second built-up structure 24b and has a plurality of second openings 250b for exposing the second conductive pads 244b, correspondingly.

According to the present invention, a core board having a first surface and an opposite second surface is provided, a semiconductor chip having an active surface and an opposite inactive surface is received in a cavity of the core board, a first reinforcing dielectric layer comprising a reinforcing material such as glass fiber is disposed on the first surface of the core board and the active surface of the semiconductor chip, and a second reinforcing dielectric layer comprising a reinforcing material such as glass fiber is disposed on the second surface of the core board and the inactive surface of the semiconductor chip. The application of the first and second reinforcing dielectric layers enhances the support force of the entire structure so as to prevent warpages of the first and second reinforcing dielectric layers which otherwise can occur due to contraction of dielectric layers during a hardening process as in the prior art. In addition, the application of the first and second reinforcing dielectric layers avoids formation of recesses as in the prior art, thereby preventing delamination of the wiring layers electrically connecting to the semiconductor chip from the dielectric layers and increasing product yield and reliability.

The above-described descriptions of the detailed embodiments are only to illustrate the preferred implementation according to the present invention, and it is not to limit the scope of the present invention, Accordingly, all modifications and variations completed by those with ordinary skill in the art should fall within the scope of present invention defined by the appended claims.

What is claimed is:

1. A packaging substrate having an embedded semiconductor chip, comprising:
a core board having a first surface and an opposite second surface and a cavity penetrating the first and second surfaces;
a semiconductor chip disposed in the cavity and having an active surface with a plurality of electrode pads and an opposite inactive surface;
a first reinforcing dielectric layer disposed on the first surface of the core board and the active surface of the semiconductor chip and filling the gap between the semiconductor chip and the cavity, wherein the first reinforcing dielectric layer comprises a reinforcing material;
a second reinforcing dielectric layer disposed on the second surface of the core board and the inactive surface of the semiconductor chip and filling the gap between the semiconductor chip and the cavity, wherein the second reinforcing dielectric layer comprises a reinforcing material; and
first and second wiring layers disposed on the first and second reinforcing dielectric layers, respectively, and the first wiring layer electrically connecting to the electrode pads.

2. The substrate of claim 1, wherein the core board is one of an insulation board, a metal board and a wiring board having an inner wiring layer.

3. The substrate of claim 1, wherein the reinforcing material is a glass fiber material.

4. The substrate of claim 1, wherein the first reinforcing dielectric layer has a plurality of vias for exposing the electrode pads, correspondingly, and conductive vias are disposed in the vias, correspondingly, so as to electrically connect the first wiring layer and the electrode pads.

5. The substrate of claim 1, further comprising a plurality of through holes penetrating the first reinforcing dielectric layer, the core board and the second reinforcing dielectric layer, and conductive through holes are disposed in the through holes, correspondingly, so as to electrically connect the first and second wiring layers.

6. The substrate of claim 1, further comprising a first built-up structure disposed on the first reinforcing dielectric layer and the first wiring layer and electrically connecting to the first wiring layer.

7. The substrate of claim 6, wherein the first built-up structure has at least a first dielectric layer, a first built-up wiring layer disposed on the first dielectric layer, and a plurality of first built-up conductive vias disposed in the first dielectric layer and electrically connecting the first wiring layer and the first built-up wiring layer, the outermost first built-up wiring layer of the first built-up structure having a plurality of first conductive pads.

8. The substrate of claim 7, further comprising a first solder mask layer disposed on the first built-up structure and having a plurality of first openings for exposing the first conductive pads, correspondingly.

9. The substrate of claim 1, further comprising a second built-up structure disposed on the second reinforcing dielectric layer and the second wiring layer and electrically connecting to the second wiring layer.

10. The substrate of claim 9, wherein the second built-up structure has at least a second dielectric layer, a second built-up wiring layer disposed on the second dielectric layer, and a plurality of second built-up conductive vias disposed in the second dielectric layer and electrically connecting the second wiring layer and the second built-up wiring layer, the outermost second built-up wiring layer of the second built-up structure having a plurality of second conductive pads.

11. The substrate of claim 10, further comprising a second solder mask layer disposed on the second built-up structure and having a plurality of second openings for exposing the second conductive pads, correspondingly.

12. The substrate of claim 1, wherein the first and second reinforcing dielectric layers are made of the same material.

13. The substrate of claim 1, wherein the first and second reinforcing dielectric layers are made of different materials.
